(19) United States
(12) Patent Application Publication
(10) Pub. No.: US 2012/0024337 A1
(43) Pub. Date: Feb. 2, 2012

(54) APPARATUS FACILITATING WIRING OF MULTIPLE SOLAR PANELS

(76) Inventors: John Bellacicco, Stamford, CT (US); Siddika Pasi, Kendall Park, NJ (US)

(21) Appl. No.: 12/846,671

(22) Filed: Jul. 29, 2010

(51) Int. Cl. H01L 31/042; H02G 3/00

(52) U.S. Cl. 136/244; 174/70 R

(57) ABSTRACT

An apparatus for electrically interconnecting a plurality of solar panels commonly mounted on a carrier. The apparatus comprises a wiring block having a pair of positive and negative wires for each of a plurality of solar panels, and positive and negative wires for accessing the solar panels of a carrier. The wiring block of a carrier interconnects the plurality of solar panels in series, or parallel, or both. The carrier can thus be pre-wired for easy field installation of a plurality of solar panels as a unit.

### FIELD OF THE INVENTION

Embodiments of the invention relate to solar panel installation, and more particularly to facilitating the wiring together of a plurality of solar panels.

### BACKGROUND OF THE INVENTION

Solar panel installation traditionally involves installing a foundation system (typically a series of posts or footings), and then mounting individual solar panels to the support frame with brackets or clips. Other, more complicated mounting systems have been proposed with multiple parts and complex assemblies. These mounting structures can be difficult to install and worse, expensive to manufacture. Additional problems can result from the diverse materials used to manufacture such mounting systems.

In known solar panel-driven power generation systems, sets of solar panels are wired in series to produce a desired voltage. These sets of wired solar panels are called strings. The strings consist of solar panels electrically connected to each other with panel lead wires. Once the strings are wired, sets of strings can be connected in parallel with wire harnesses to add the currents from each string, until the connected sets provide a desired current. Each individual solar panel in such a system, however, must be separately wired in series and/or parallel configurations with other solar panels of the system. Typically, this wiring is performed on-site and one panel at a time, requiring moving equipment, materials and labor along rows of support structures. This is time-consuming and increasingly inefficient with larger scale systems. Thus, a simplified system for wiring a plurality of solar panels together is needed.

### BRIEF DESCRIPTION OF THE DRAWINGS

FIG. 1A shows a top-down view of a carrier with a plurality of solar panels mounted thereon.

FIG. 1B shows a partial top-down view of a carrier with plugs having a plurality of solar panels mounted thereon.

FIG. 2 shows a top-down view of the FIG. 1B carrier with the plugs and solar panels aligned along a central axis.

FIG. 3A is a schematic diagram of a portion of a power generation system having a plurality of carriers and showing a possible series electrical connection between adjacent solar panels in a row, with rows of solar panels connected in parallel.

FIG. 3B is a schematic diagram of a single row of solar panels in the FIG. 3A system.

FIG. 4A is a top-down view of the FIG. 2 carrier having a wiring block for interconnecting the plurality of solar panels installed thereon.

FIG. 4B is a close-up top-down view of a portion of the FIG. 4A carrier.

FIG. 4C is a side view of the FIG. 4A carrier with a wiring block mounted on the interior of the carrier.

FIG. 4D is a side view of the FIG. 4A carrier with a wiring block mounted on the exterior of the carrier.

FIG. 5 is a top-down view of the wiring block illustrated in FIGS. 4A and 4B.

FIG. 6A is a schematic diagram of the internal components of a FIGS. 4A and 4B wiring block configured to electrically connect solar panels of a carrier in parallel.

FIG. 6B is a schematic diagram of the internal components of a FIGS. 4A and 4B wiring block configured to electrically connect solar panels of a carrier in series.

FIG. 7 is a top-down view showing a plurality of FIG. 2 carriers connected together with FIG. 6A wiring blocks installed thereon.

FIG. 8 is a schematic diagram of a portion of a power generation system having multiple interconnected groups of solar panels on a plurality of carriers

FIGS. 9A, 9B, and 9C are schematic diagrams showing series, parallel, and hybrid series/parallel wired carriers, respectively.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein without departing from the spirit or scope of the invention.

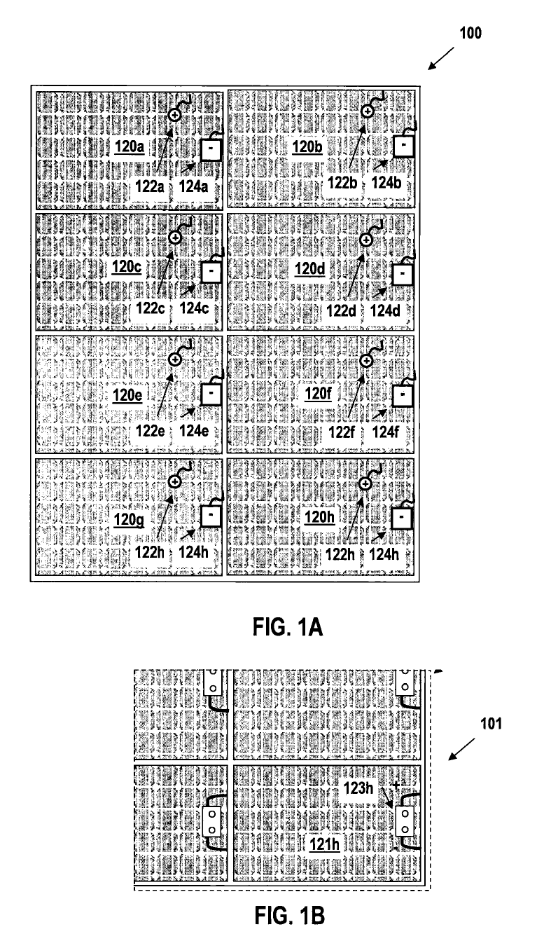

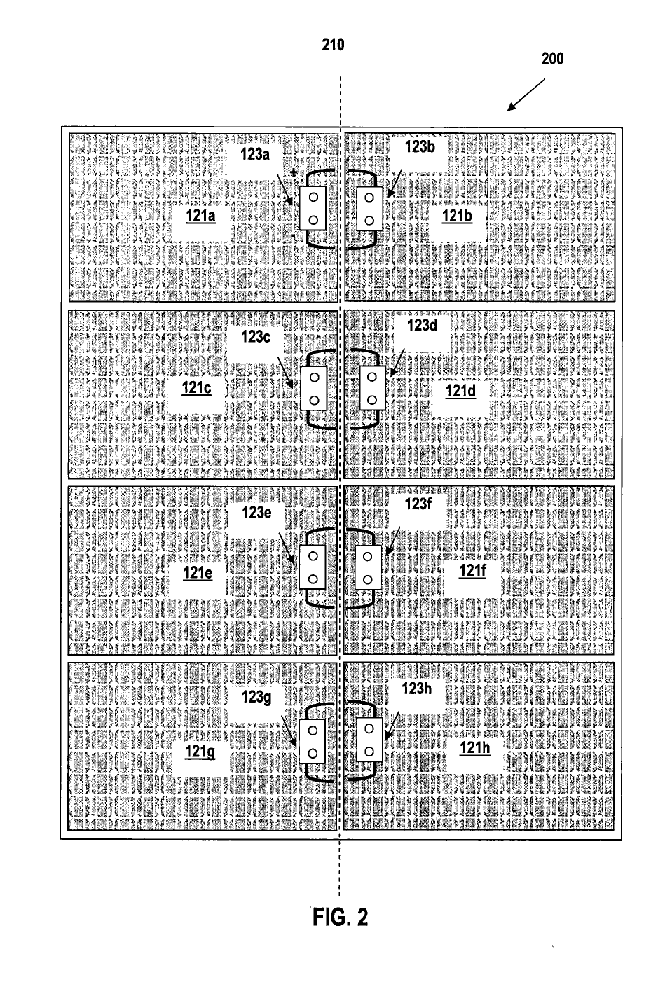

By way of background, FIGS. 1A, 1B and 2 show examples of solar panel carriers as described in co-pending application Ser. No. 12/______ entitled “A MOUNTING SYSTEM SUPPORTING SLIDABLE INSTALLATION OF A PLURALITY OF SOLAR PANELS AS A UNIT” by John Bellacicco, John Hartelius, Henry Cabuhay, Tom Kuster, Michael Monaco, and Martin Perkins. (attorney docket no. F4500.1001/P1001), filed on even date with this application, the disclosure of which is fully incorporated by reference herein. Solar panel carriers 100, 101, 200, respectively shown in FIGS. 1A, 1B and 2, hold a plurality of solar panels together as a single unit and provide a way of installing the plurality of solar panels as a unit onto a support structure in a manual or semi-automated installation system. Such solar panel carriers (e.g., carrier 100 in FIG. 1A) support simplified installation of solar panels, reducing both on-site field labor and equipment movement over an installation site. The solar panel carriers can be easily installed on a support structure, e.g., one comprising a plurality of spaced parallel rails designed to slidably accept the carrier.

FIG. 1A shows one exemplary solar panel carrier 100 with a plurality of solar panels 120a-120h pre-mounted thereon. The carrier 100 is depicted having 4 rows and 2 columns of solar panels 120a-h, but is understood that the carrier can have any number of solar panels arranged in an M rows×N column array. Each solar panel 120a-h has a set of positive and negative terminals 122a-h, 124a-h, shown in FIG. 1A with pigtail wires. The terminals 122a-h, 124a-h connect to the solar cells within an individual solar panel. The solar panels 120a-h in carrier 100 are aligned in the same direction; that is, the terminals 122a-h, 124a-h on each panel are oriented on right hand side of the solar panels 120a-h mounted on carrier 100. It is, however, of course understood that solar panels 120a-h can be oriented in any direction on carrier 100.

FIG. 1B shows another exemplary solar panel carrier 101 having a different arrangement of positive and negative terminals for solar panels 121a-h mounted thereon. The solar panels 121a-h of the FIG. 1B carrier 101 each have a plug 123a-h which contains positive and negative contacts that engage a corresponding receptacle on the carrier 101. Alternatively, the carrier 101 can have the plug and the panel can have the receptacle.

FIG. 2 shows carrier 200 with solar panels 121a-h installed thereon, each having plug/receptacles 123a-h. The solar panels 121a-h are installed on carrier 200 in an orientation which aligns plug/receptacles 123a-h along a central axis 210. This type of arrangement simplifies the general location of wiring on the carrier 200 as all the wiring of the solar panels 121a-h can be routed along the axis 210.

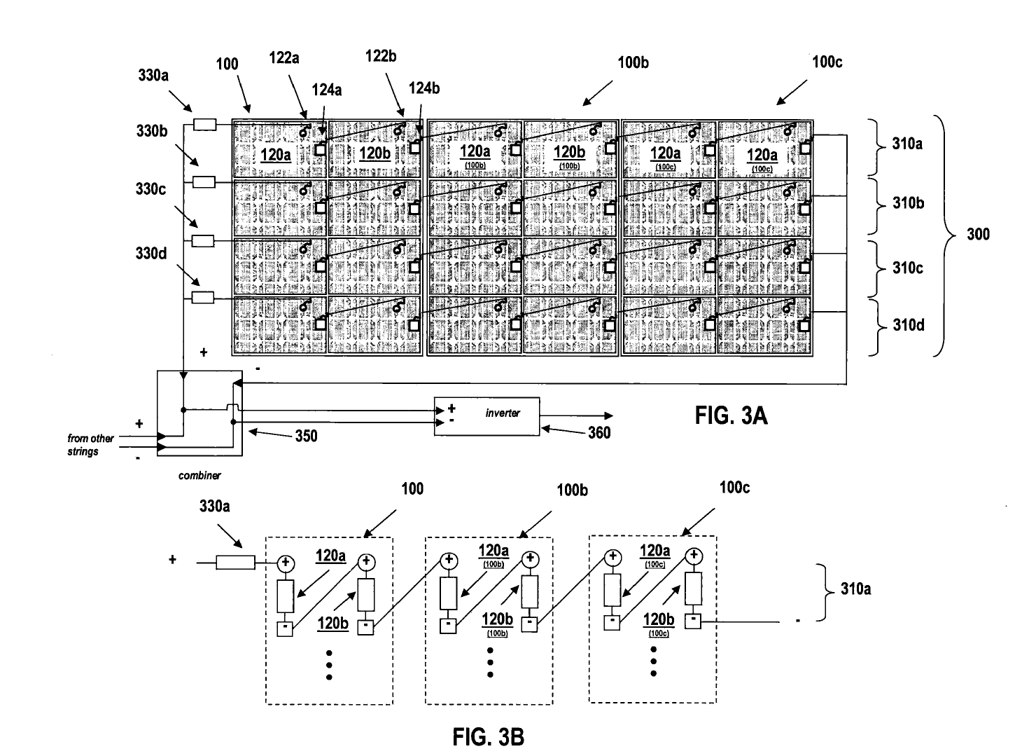

FIG. 3A shows one possible arrangement for wiring a plurality of solar panels 120a-h of each of carriers 100, 100b, 100e (FIG. 1A) together. The panels in each row of arranged carriers 100, 100b, 100c are wired in series to form a solar panel string 310a, 310b, 310c, 310d. Each solar panel string 310a, 310b, 310c, 310d can be equipped with protection device or circuitry 330a, 330b, 330c, 330d, e.g., a fuse, diode, circuit breaker or other protection device or circuit.

As FIG. 3A shows, in a first series solar panel string, e.g., 310a, the positive and negative terminals 122a, 122b, 124a, 124b on solar panels 120a and 120b on carrier 100 are wired to each other. The rightmost solar panel in the row (120b) on carrier 100 is wired to the leftmost panel of the next carrier in the series. Wiring continues until a desired number of panels are connected to the series string 310a attain a desired string voltage. FIG. 3B shows an electrical schematic of a series string 310a. The positive end of a series solar panel string 310a is connected to a protection device or circuit 330a. The last solar panel in the series on carrier 100c provides a negative end of the string 310a.

Because there are multiple rows of solar panels on each carrier 100, 100b, 100c, arranged carriers create multiple series solar panel strings 310a, 310b, 310c, 310d, which may be electrically connected together in parallel to form a group 300 of solar panels, as shown in FIGS. 3A and 3B. The parallel-wired series strings 310a, 310b, 310c, 310d may be electrically connected to a combiner 350, which aggregates the electrical energy generated by the solar panel strings in group 300 together with that of other solar panel strings to attain a desired voltage and current. The combined electrical output from combiner 350 is fed to an inverter 360. It should be understood that although 4 series solar panel strings 310a, 310b, 310c, 310d of 6 solar panels, 2 from each row of carriers 100, 100b, 100c are shown in FIG. 3A, any number of series solar panel strings, or panels per string could be used as needed to meet a desired current and/or voltage.

While FIGS. 3A and 3B show one possible wiring configuration for the solar panels held by each of a plurality of carriers, e.g., 100, 100b, 100c, it should be apparent that wiring the solar panels in the field in the manner illustrated in FIGS. 3A and 3B is a time consuming and labor intensive process.

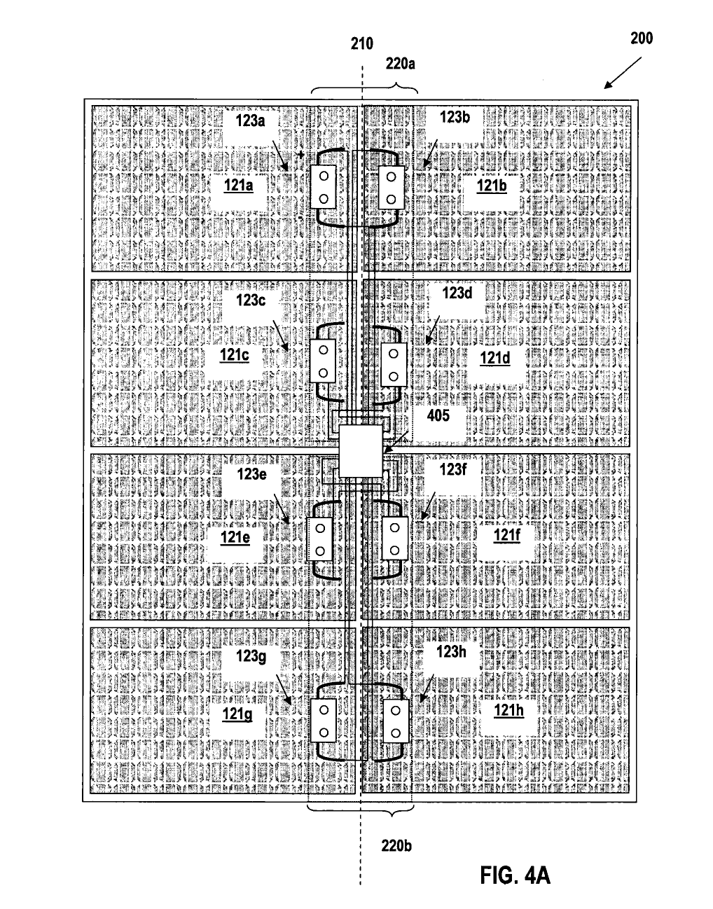

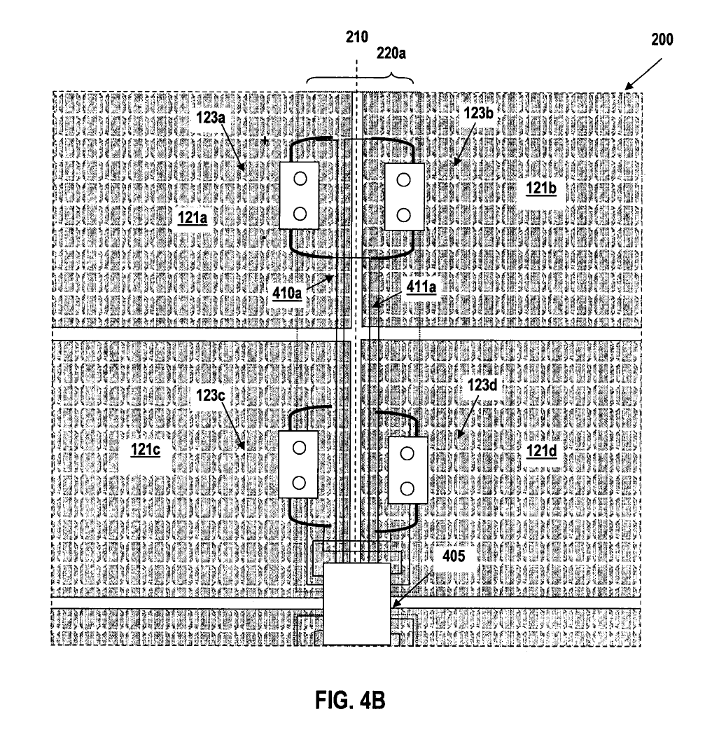

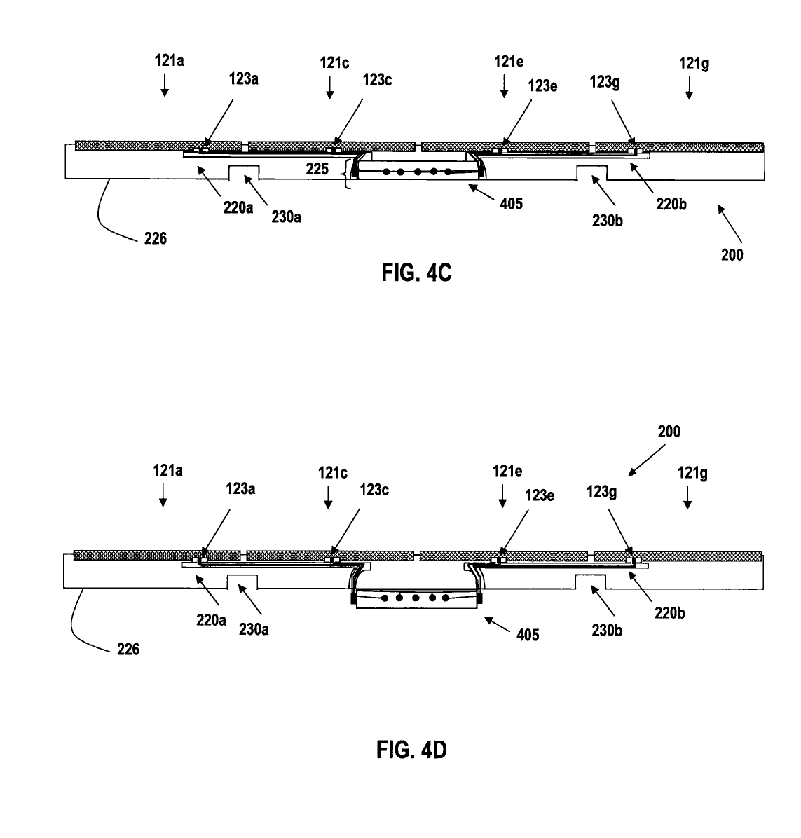

In order to facilitate the wiring together of the individual solar panels, e.g., 120a-h, mounted on a carrier, e.g., 100, and the wiring of a carrier 100 to other carriers, e.g., 100b, 100c, etc., a wiring block 405 is preferably provided on each carrier, for example carrier 200 of FIG. 2A in the manner shown in FIGS. 4A and 4B. FIG. 4A shows wiring block 405 as electrically interconnecting a plurality of solar panels, e.g., 121a-h. The solar panels 121a-h are preferably mounted on the carrier 200 so that all wiring is near the center line axis 210 of the carrier 200. The wiring block 405 is connected by wires to each of the plug/receptacles 123a-h on the carrier 200, although the wiring block 405 can be directly wired to pigtail wiring, e.g., terminals/wiring 122a-h, 124a-h of the FIG. 1A carrier 100, as well. The wires can optionally be run through channels 220a, 220b, provided within or beneath carrier 200. FIG. 4B shows a close up view of solar panel 121a on carrier 200 having positive wire 410a and negative wire 411a from wiring block 405 connected to corresponding plug/receptacle 123a. Connections from wiring block 405 to plugs/receptacles 123b, 123c and 123d and other panels are also shown.

As shown in FIG. 4C, wiring block 405 can be attached to the carrier 200 in a recess or channel 225 provided within the backside 226 of carrier 200. Alternatively, as shown in FIG. 4D, carrier 200 can be mounted directly on a backside 226 of carrier 200. FIGS. 4C and 4D also show channels 220a, 220b for passage of wires from wiring block 405 to solar panels 121a-h. Channels 220a, 220b can be run in the body of carrier 200, and are shown in FIGS. 4C-4D as being positioned above attachment structures 230a, 230b, which are used to mount the carrier 200 to a support structure.

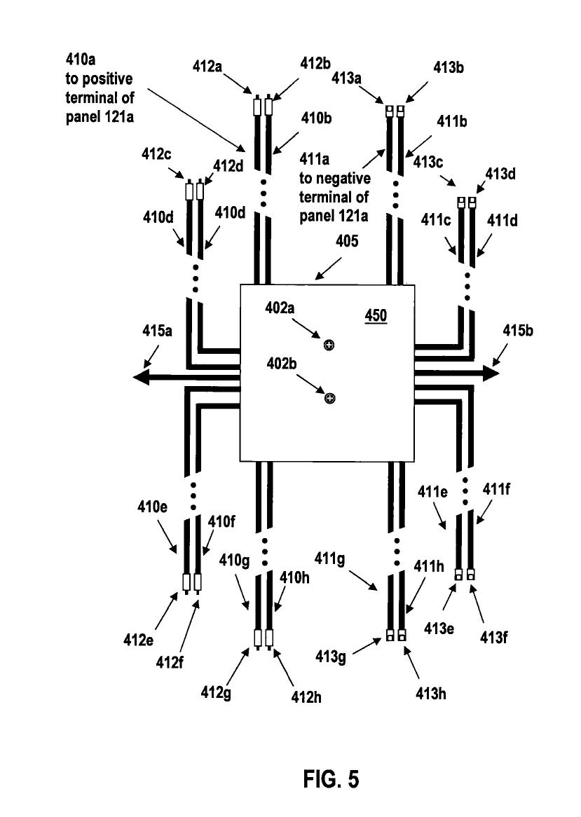

FIG. 5 shows the exterior of one embodiment of wiring block 405. The wiring block 405 is contained in a protective housing 450 which is secured to a carrier, e.g., 200 by means of threaded screw mounts 402a, 402b which align with holes or screw mounts on the backside of carrier 200. Of course it is understood that other securing materials, e.g., glue, Velcro®, or other conventional fasteners can be also used. A plurality of positive and negative wires 410a-h, 411a-h exit the wiring block 405 to facilitate easy connection to the plug/receptacles, e.g., 123a-h, on the carrier 200. Each pair of positive and negative wires, e.g., 410a, 411a, is connectable to the respective positive and negative wires on a respective solar panel 121a. The positive and negative wires 410a-h, 411a-h are equipped with a corresponding connector 412a-h, 413a-h, which can be one of a Multi Contact 4 (MC4) and Yamaichi YSol 4 connector, which are commonly used with solar panels, for connection to, e.g., plug/receptacles 123a-h on the carrier 200. It is of course understood that other connectors could be used as well. Additionally, a pair of positive and negative conductors 415a, 415b for connecting adjacent wiring blocks 405 on adjacent carriers 200 are arranged on opposite sides of the wiring block 405. These too may have Multi Contact 4 (MC4) or Yamaichi YSol 4 connectors attached so as to allow easy connection of one carrier 200 to another. If plugs/receptacles 123a-h are note used, the positive and negative wires 410a-h can be directly connected to the pigtail wires, e.g., 122a, 124a (FIG. 1A) on the solar panels.

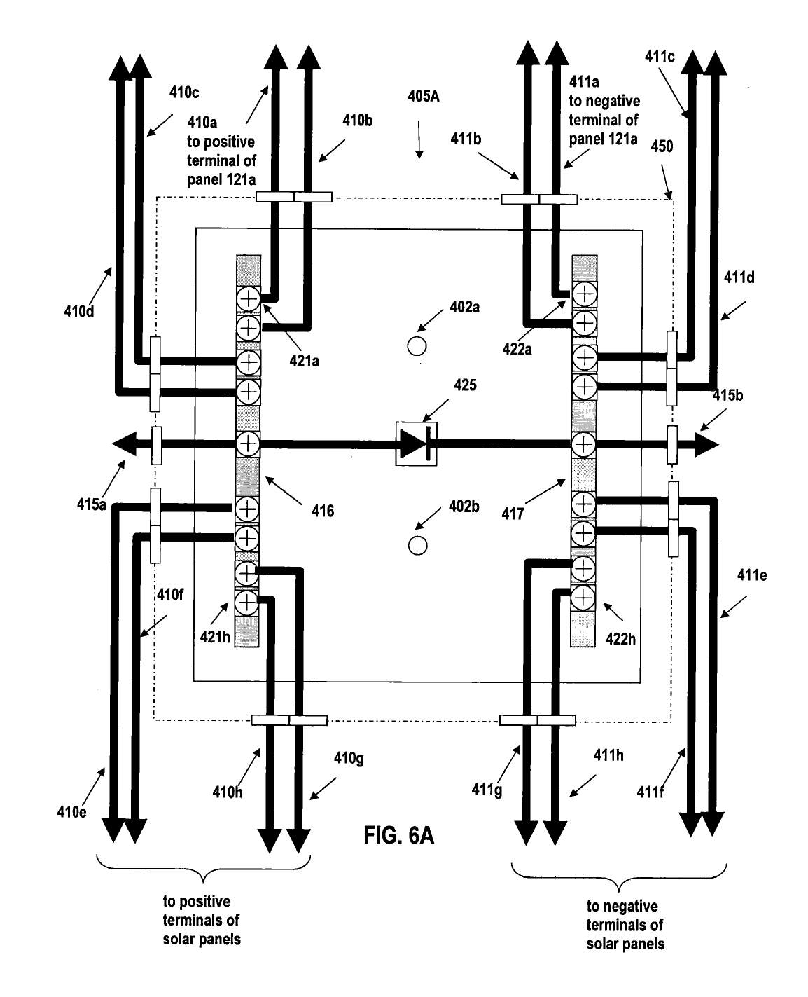

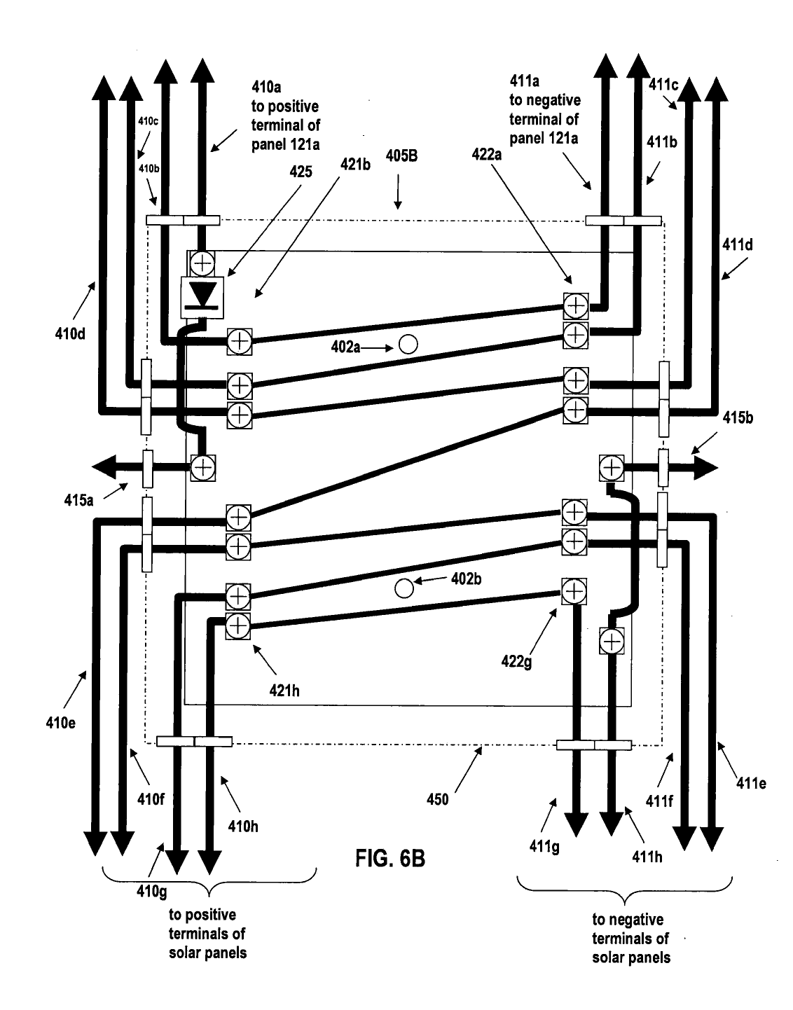

FIG. 6A shows an interior schematic of one embodiment of a wiring block 405A configured to electrically connect attached all solar panels 121a-h on a carrier 200 in parallel. The plurality of positive and negative wires 410a-h, 411a-h respectively connect to a corresponding pair of busbars 416, 417 using screw-down wire fasteners 421a-h, 422a-h. Other means of fastening the wires to the busbars 416, 417 can be used, including, for example, clip fasteners, or soldering. Positive and negative conductors 415a, 415b are also connected to busbars 416, 417, respectively, to allow interconnection of the solar panels from one carrier with those of another through the electrical connection of the wiring block 405 of one carrier with the wiring block 405 of another carrier, as explained in greater detail below. To prevent damage to the connected solar panels, busbars 416, 417 are bridged by a protection circuit, preferably a bypass diode 425. Generally, current will flow across busbars 416, 417 so long as the bypass diode 425 is not tripped by a positive overvoltage. If there is a short to ground on the cartridge, as long as the voltage on the diode is negative, the cartridge will supply current at a diminished level. However, if there is a short to ground where the voltage on the diode is positive then the cartridge will experience reverse voltage bias, tripping the diode. Other protection circuitry comprising blocking diodes, circuit breakers, or fuses can also be used in addition or substituting for to the bypass diode to prevent damage to solar panels within the cartridge, if required.

FIG. 6B shows an interior schematic of another embodiment of a wiring block 405B configured to electrically connect solar panels 121a-h of carrier 200 in series. In FIG. 6B the screw-down wire fasteners 421b-h, 422a-g are wired together to facilitate a series wiring of corresponding solar panels 121a-h. As an example, fastener 422a, which corresponds to the negative input from a first solar panel 121a, is wired to fastener 421b, which corresponds to the positive input from a second solar panel 121b. The positive input from the first solar panel 121a may connect to a bypass diode, fuse, circuit breaker, or other protection device or circuit 425 to cross-connector 415a for positive output. At the opposite end of the series, the negative input from the last solar panel 121h is connected to negative conductor 415b for negative output from carrier 200. Although FIGS. 6A and 6B respectively illustrate wiring blocks 405 which interconnect the solar panels of a carrier in parallel or series, the wiring block 405 can also be internally configured to wire some panels on a carrier in series and others in parallel.

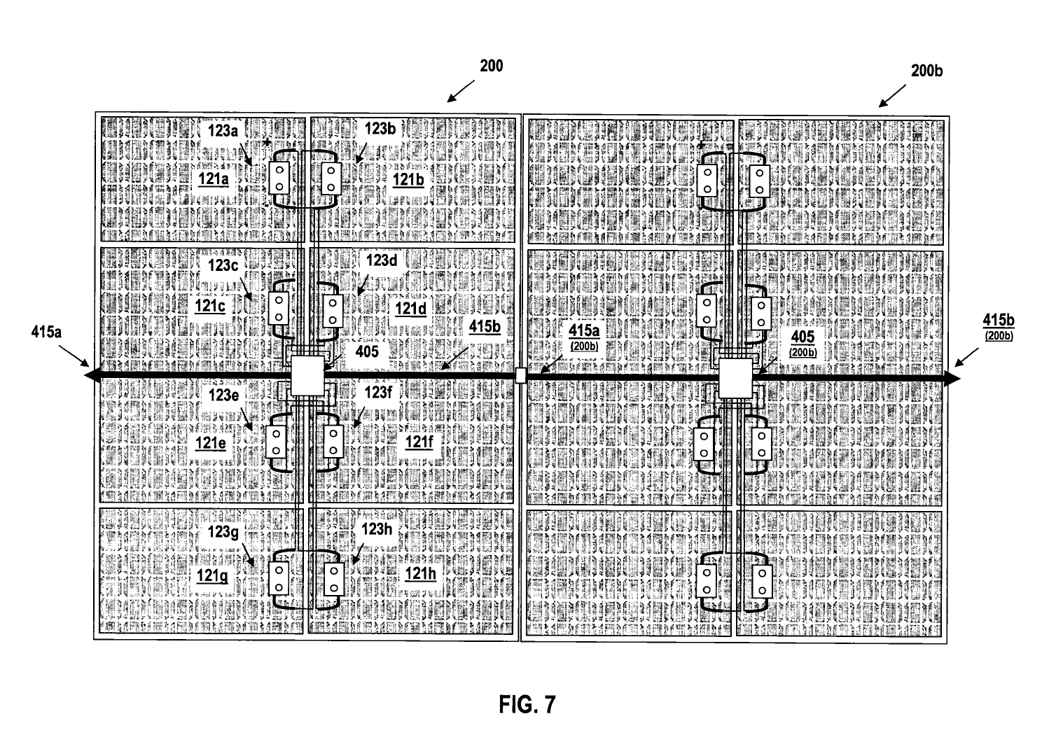

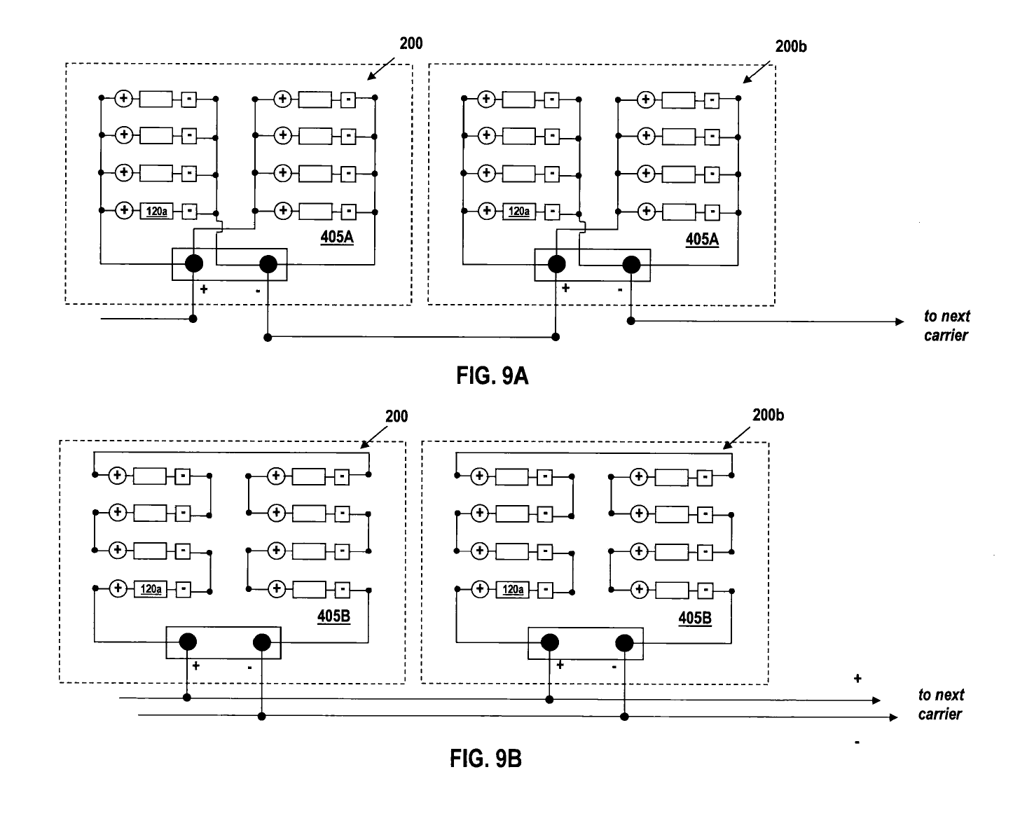

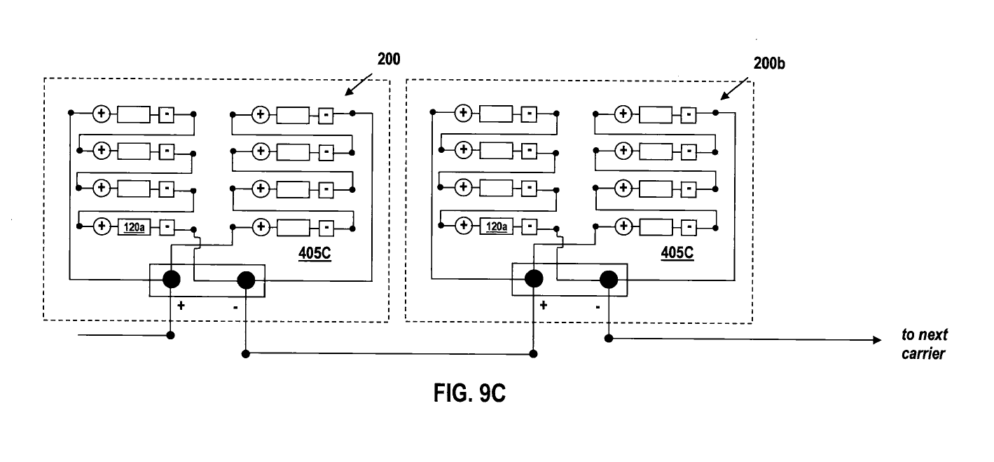

FIG. 7 shows a set of FIG. 2 carriers 200, 200b (and associated solar panels 121a-h and plug/receptacles 123a-h) connected in series via the positive and negative conductors 415a, 415b connected to their wiring blocks 405. FIGS. 9A and 9B show electrical schematic diagrams of series and parallel wired FIG. 2 carriers 200, 200b with wiring blocks 405A (FIG. 9A) and 405B (FIG. 9B) wired in parallel and series, respectively. FIG. 9C shows a hybrid wiring scheme in wiring blocks 405C which two sets of four solar panels on a carrier 200, 200b are wired in series and the sets then are wired in parallel, with the carriers 200, 200b then being wired in series. Alternatively, the solar panels could be wired in parallel and the sets in series.

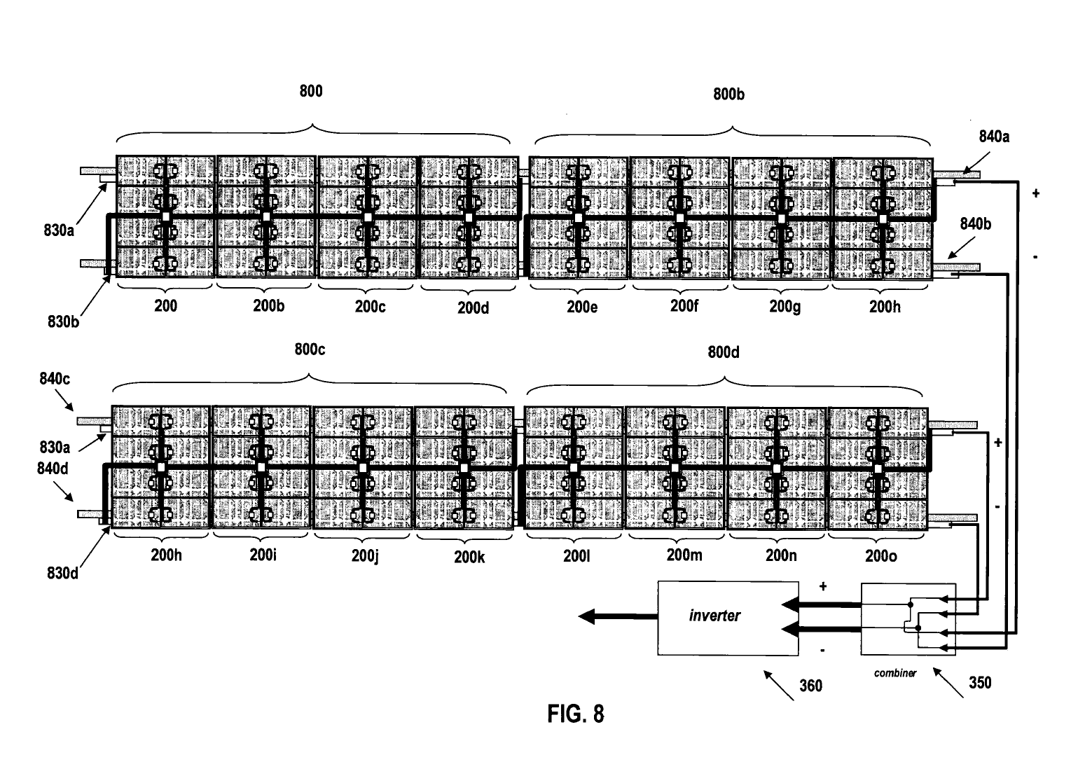

FIG. 8 shows a power generating system comprising a plurality of carriers 200-200o formed into carrier groups 800, 800b, 800c, and 800d which are mounted on support rails 840a, 840b, 840c, 840d. Each of the carriers 200-200o contains a respective wiring block 405 (FIG. 6A). The solar panels of each carrier are wired in parallel through a wiring block 405, while the carriers of each group 800, 800b, 800c, 800d are wired in series. For example, the carriers 200, 200a, 200b, 200c are wired in series. The carrier groups 800 and 800b are respectively wired in parallel to a positive busway 830a and a negative busway 830b, and the carrier groups 800c and 800d are wired in parallel to fused positive busway 830c and fused negative busway 840d, or individually home run to a combiner, e.g., 350.

The positive and negative busways 830a, 830b, 830c, 830d form an electrical group. As shown in FIG. 8, each of the positive busways 830a, 830c may be respectively mounted on to one of the spaced parallel rails 840a, 840c, which mount the carriers, and the negative busways 830b, 830d are mounted to the other of the carrier mounting rails 840b, 840d. Alternatively, the busways 830a, 830b can run along the ground or on a roof or side of a building, depending on where the carriers are installed. The carrier groups 800a, 800b and 800c, 800d are wired in parallel by a combiner 350 to an inverter 360.

Generally, a semi-automated carrier mounting and delivery system may be used at the end of each solar array row to push carriers, e.g., those in groups 800, 800b, 800c, 800d, in to place on rails 840a, 840b. One such mounting and delivery system is described in more detail in co-pending application Ser. No. 12/______, entitled “AUTOMATED INSTALLATION SYSTEM FOR AND METHOD OF DEPLOYMENT OF PHOTOVOLTAIC SOLAR PANELS, to John Bellacicco, Tom Kuster, Michael Monaco and Tom Oshman (attorney docket no. F4500.1002/P1002), filed on even date with this application, the disclosure of which is incorporated by reference herein. As discussed in that application, each carrier mounts and supports a plurality of solar panels as a unit, is set on the rails by a robotic system and moved along, thereby simplifying installation time and lowering cost. Once in place, since each of the solar panels on the carriers are pre-wired, only carrier to carrier wiring needs to be done on site. To further facilitate installation, positive and negative male/female electrical connectors can be provided on the edge of the carriers e.g., 200, so that when the carriers are pushed into place, the male and female connectors interconnect the wiring blocks 405 on the carriers, e.g., 200. Then all that is needed to do is to connect each carrier group, e.g., 800 to positive and negative busways, e.g., 830a, 830b or combiner 350, substantially reducing the on-site labor required for installation.

While several embodiments have been described in detail, it should be readily understood that the invention is not limited to the disclosed embodiments. Rather the embodiments can be modified to incorporate any number of variations, alterations, substitutions or equivalent arrangements not heretofore described. Although certain features have been described with some embodiments of the carrier, such features can be employed in other embodiments of the carrier as well. Accordingly, the invention is not limited by the foregoing description, but is only limited by the scope of the appended claims.

What is claimed as new and desired to be protected by Letters Patent of the United States is:

1. An apparatus for electrically interconnecting a plurality of solar panels mounted on a carrier, said apparatus comprising:
a wiring block mounted on said carrier for electrically interconnecting said plurality of solar panels and providing electrical access to said plurality of interconnected solar panels.

2. The apparatus of claim 1, further including busbars within said wiring block to which said plurality of solar panels are connected.

3. The apparatus of claim 2, further comprising electrical protection circuitry coupled to said electrical access provided by said wiring block.

4. The apparatus of claim 3, wherein said protection circuitry comprises a diode.

5. The apparatus of claim 3, wherein said protection circuitry comprises a circuit breaker.

6. The apparatus of claim 3, wherein said protection circuitry comprises a fuse.

7. The apparatus of claim 1, wherein said wiring block provides a respective pair of positive and negative wires connected to each solar panel and another pair of positive and negative wires for providing electrical access to said plurality of solar panels.

8. The apparatus of claim 7, wherein each of said pair of positive and negative wires have respective connectors for connecting to a solar panel.

9. The apparatus of claim 1, wherein said wiring block is secured to a backside of said carrier.

10. The apparatus of claim 9, wherein said wiring block is secured within a recess on said backside of said carrier.

11. The apparatus of claim 9, wherein said wiring block is secured within a channel in said backside of said carrier.

12. The apparatus of claim 1, wherein said wiring block electrically interconnects said solar panels in parallel.

13. The apparatus of claim 1, wherein said wiring block electrically interconnects said solar panels in series.

14. The apparatus of claim 1, wherein said wiring block electrically interconnects groups of said plurality of solar panels in series and electrically interconnects said groups in parallel.

15. The apparatus of claim 1, wherein said wiring block electrically interconnects groups of said plurality of solar panels in parallel and electrically interconnects said groups in series.

16. The apparatus of claim 7, wherein said positive and negative wires for a respective solar panel are connected to a receptacle configured to accept a corresponding plug on respective positive and negative wires of said solar panel.

17. The apparatus of claim 7, wherein said positive and negative wires for a respective solar panel are connected to a plug configured to engage a corresponding receptacle on respective positive and negative wires of said solar panel.

18. The apparatus of claim 7, wherein said positive and negative wires are disposed in channels in said carrier.

19. The apparatus of claim 17, wherein said channels are arranged along a center of said carrier.

20. The apparatus of claim 7, wherein said pair of positive and negative wires for providing electrical access to said plurality of solar panels are connected to other carriers.

21. A system for generating power, said system comprising:
An interconnected plurality of carriers, each carrier having a plurality of solar panels mounted thereon and a wiring block for electrically interconnecting said plurality of solar panels and providing electrical access to said plurality of interconnected solar panels.

22. The system of claim 21, wherein said interconnected plurality of carriers is divided into a plurality of groups, said carriers in each group being connected in series.

23. The system of claim 22, wherein each group is electrically connected in parallel to a set of positive and negative busways.

24. The system of claim 23, further including a second interconnected plurality of carriers divided into a second plurality of groups, said carriers in each group being electrically connected in series and each group being electrically connected in parallel to a second set of positive and negative busways.

25. The system of claim 23, wherein said positive and negative busways are electrically connected to a combiner.

26. The system of claim 25, wherein said combiner is electrically connected to an inverter.

27. The system of claim 21, wherein said plurality of carriers are mounted on a pair of parallel spaced rails.

28. The system of claim 23, wherein said plurality of carriers are mounted on a pair of parallel spaced rails and said positive and negative busways are mounted to one of said parallel spaced rails.

29. The system of claim 21, further including busbars within each wiring block to which said plurality of solar panels on said carrier are connected.

30. The system of claim 21, further comprising electrical protection circuitry coupled to said electrical access provided by said wiring block.

31. The system of claim 30, wherein said protection circuitry comprises a diode.

32. The system of claim 30, wherein said protection circuitry comprises a circuit breaker.

33. The system of claim 30, wherein said protection circuitry comprises a fuse.

34. The system of claim 21, wherein each wiring block provides a respective pair of positive and negative wires connected to each solar panel and another pair of positive and negative wires for providing electrical access to said plurality of solar panels on said carrier.

35. The system of claim 34, wherein each of said pair of positive and negative wires have respective connectors for connecting to a solar panel.

36. The system of claim 21, wherein each wiring block is secured to a backside of each carrier.

37. The system of claim 36, wherein each wiring block is secured within a recess on said backside of each carrier.

38. The system of claim 21, wherein each wiring block electrically interconnects said solar panels on each carrier in parallel.

39. The system of claim 21, wherein each wiring block electrically interconnects said solar panels on each carrier in series.

40. The system of claim 21, wherein each wiring block electrically interconnects groups of each plurality of solar panels on each carrier in series and electrically interconnects said groups in parallel.

41. The system of claim 21, wherein each wiring block electrically interconnects groups of each plurality of solar panels on each carrier in parallel and electrically interconnects said groups in series.

42. The system of claim 34, wherein said positive and negative wires for a respective solar panel are connected to a receptacle configured to accept a corresponding plug on respective positive and negative wires of said solar panel.

43. The system of claim 34, wherein said positive and negative wires for a respective solar panel are connected to a plug configured to engage a corresponding receptacle on respective positive and negative wires of said solar panel.

44. The system of claim 34, wherein said positive and negative wires are disposed in channels in each carrier.

45. The system of claim 34, wherein said channels are arranged along a center of each carrier.
